(19) United States
(12) Patent Application Publication
(10) Pub. No.: US 2008/0061404 A1
(43) Pub. Date: Mar. 13, 2008

(54) Electronic circuit package and fabricating method thereof

(75) Inventors: Shi-Yun Cho, Anyang-si (KR); Young-Min Lee, Yongin-si (KR); Youn-Ho Choi, Suwon-si (KR); Ho-Seong Seo, Suwon-si (KR); Sang-Hyun Kim, Yongin-si (KR)

Correspondence Address: CHA & REITER, LLC, 210 ROUTE 4 EAST STE 103, PARAMUS, NJ, 07652, US

(73) Assignee: Samsung Electronics Co.; LTD

(21) Appl. No.: 11/895,430

(22) Filed: Aug. 24, 2007

(30) Foreign Application Priority Data
Sep. 12, 2006 (KR) 2006-88070

(51) Int. Cl. H01L 23/552; H01L 21/56

(52) U.S. Cl. 257/659; 438/127; 257/E21.504; 257/E23.114

(57) ABSTRACT

An electronic circuit package and fabricating method thereof. The method includes: integrating a radio frequency circuit device and a semiconductor die on a printed circuit board; forming a bumper pad of metal on the printed circuit board around the radio frequency circuit device; forming a molding on the printed circuit board to include the radio frequency circuit device and the semiconductor die therein; and forming one or more grooves on a portion of the molding and inserting a can into the grooves. The electronic circuit package includes: a printed circuit board; a radio frequency circuit device and a semiconductor die integrated on the printed circuit board; a molding formed on the printed circuit board to include the radio frequency circuit device and the semiconductor die therein; one or more grooves formed in the molding to enclose the radio frequency circuit device; and a can inserted into the grooves.

### CLAIM OF PRIORITY

This application claims priority an application entitled “Electronic Circuit Package and Fabricating Method Thereof,” filed in the Korean Intellectual Property Office on Sep. 12, 2006 and assigned Serial No. 2006-88070, the contents of which are hereby incorporated by reference.

### BACKGROUND OF THE INVENTION

1. Field of the Invention

The present invention relates to a package in which a plurality of electric devices is integrated, and more particularly, to an electronic circuit package including electromagnetic wave shielding means.

2. Description of the Related Art

A conventional electronic circuit package includes one or more radio frequency integrated circuits and peripheral circuits thereof. A structure in which a module is entirely mounted in a metal can has been proposed to electrically and magnetically shield an electronic circuit package or SIP, which are provided with element having electrically or magnetically sensitive characteristic.

FIG. 1 is a schematic sectional view showing the conventional electronic circuit package, and its configuration. Referring to FIG. 1, the conventional electronic circuit package 100 includes a printed circuit board 120 having a multilayered integration structure; a bump chip 101 arranged on the printed circuit board 120; a plurality of electric elements 102, 103, and 104; a radio frequency integrated circuit 105 arranged on a lower portion of the printed circuit board 120; and a metal can 110 that covers the printed circuit board 120, while enclosing the bump chip 101 and the plurality of electric elements 102, 103, and 104.

Where a plurality of integrated circuits is mounted on a single package and where high-performance and multifunctional micro electronic devices are required, the conventional electronic circuit package 100 has several problems. In conventional electronic circuit package 100, the structure of the electromagnetic wave shield applied between circuits is complex. In addition, in the conventional electronic circuit package, it is impossible to shield only a specific element using a metal can.

### SUMMARY OF THE INVENTION

Accordingly, the present invention has been made to solve the above-mentioned problems occurring in the prior art and provides additional advantages, by providing an electronic circuit package having a plurality of integrated circuits is integrated thereon and capable of shielding electromagnetic waves between the integrated circuits.

According to an aspect of the present invention, there is provided a method for fabricating an electronic circuit package comprising integrating at least one radio frequency circuit device and a semiconductor die on a printed circuit board; forming a bumper pad made of metal material on the printed circuit board so as to enclose a circumference of the radio frequency circuit device; forming a molding on the printed circuit board including the radio frequency circuit device and the semiconductor die; and forming grooves on a portion of the molding and inserting a can with an open lower portion into the grooves.

According to another aspect of the present invention, there is provided an electronic circuit package comprising: a printed circuit board; at least one radio frequency circuit device and semiconductor die integrated on the printed circuit board; a molding formed on the printed circuit board so as to include the radio frequency circuit device and the semiconductor die; grooves formed in the molding to enclose the circumference of the radio frequency circuit device; and a can inserted into the grooves.

### BRIEF DESCRIPTION OF THE DRAWINGS

The above features and advantages of the present invention will be more apparent from the following detailed description taken in conjunction with the accompanying drawings, in which:

FIG. 1 is a view showing the conventional electronic circuit package; and

FIGS. 2 to 5 are sectional views showing an electronic circuit package according to the present invention, in which the structure of the electronic circuit package is shown according to fabrication steps.

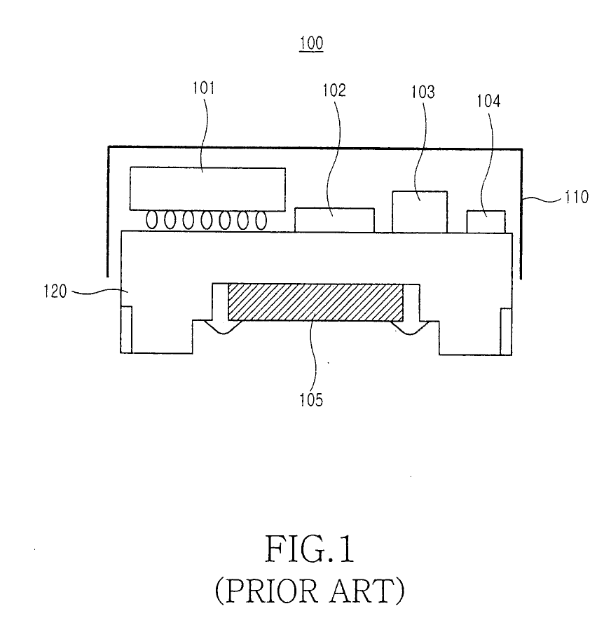

### DETAILED DESCRIPTION OF THE PRESENT INVENTION

Hereinafter, the exemplary aspects of the present invention will be described in detail with reference to the accompanying drawings. For purposes of clarity and simplicity, a detailed description of known functions and configurations incorporated herein is omitted to avoid making the subject matter of the present invention unclear.

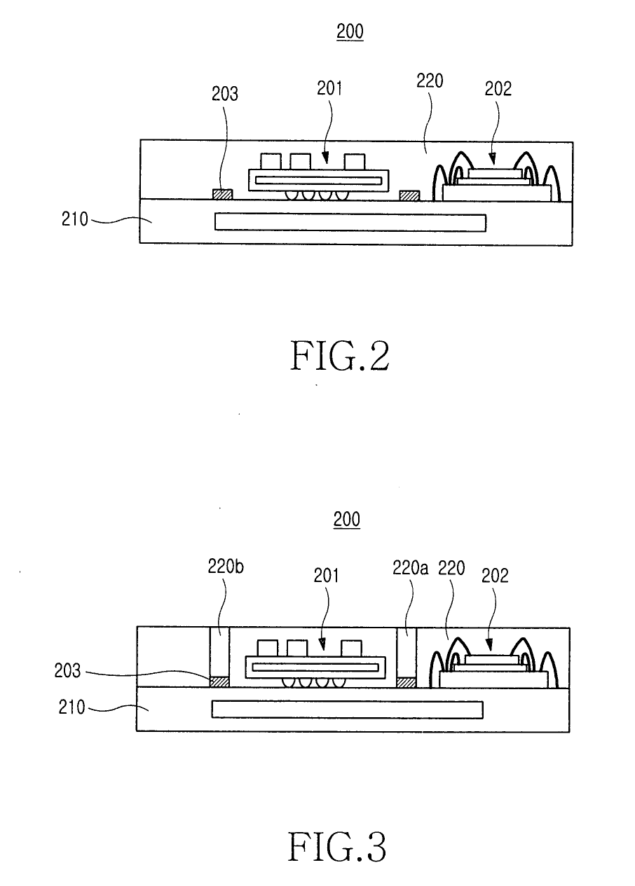

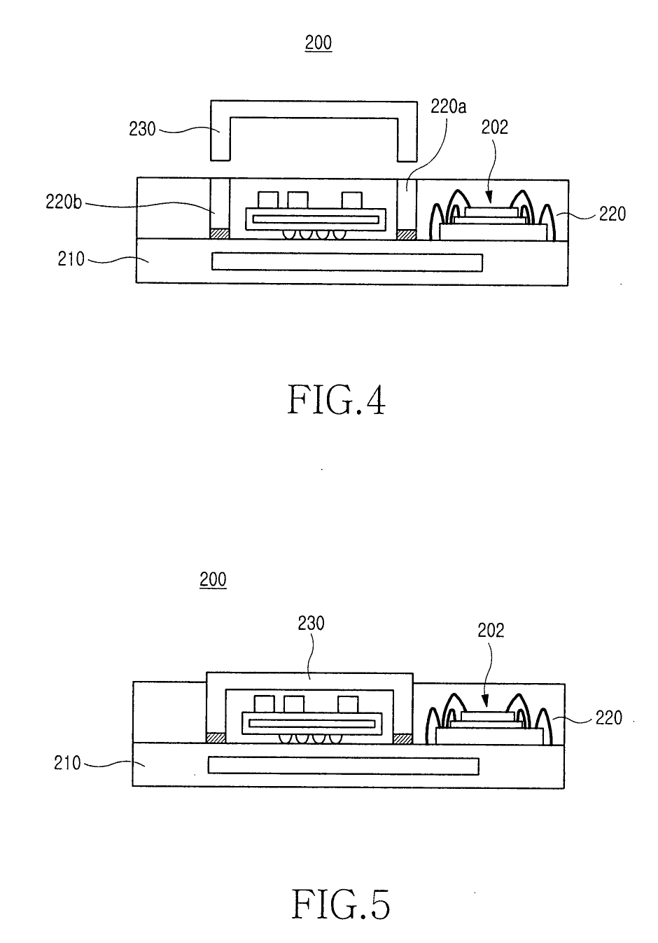

FIGS. 2 to 5 are sectional views showing an electronic circuit package according to one aspect of the present invention, in which the structure of the electronic circuit package is shown according to fabricating steps. Referring to FIGS. 2 to 5, the electronic circuit package 200 according to one aspect of the present invention includes a printed circuit board 210; at least one radio frequency circuit device 201 and semiconductor die 202 integrated on the printed circuit board 210; a molding 220 formed on the printed circuit board 210 so as to include the frequency circuit device 201 and the semiconductor die 202 therein; grooves 220a and 220b formed in the molding to enclose the radio frequency circuit device 201 and a can 230 inserted in the grooves 220a and 220b. The electronic circuit package 200 can be fabricated by the following method.

The method for fabricating the electronic circuit package 200 according to the present invention includes a first step of integrating at least one radio frequency circuit device 201 and a semiconductor die 202 on a printed circuit board 210; a second step of forming a bumper pad 203 of metal material on the printed circuit board 210 so that the bumper pad 203 encloses the radio frequency circuit device 201; a third step of forming a molding 220 on the printed circuit board 210 so that the molding 220 includes the radio frequency circuit device 201 and the semiconductor die 202 therein; and a fourth step of forming grooves 220a and 220b on a portion of the molding 220 and inserting a can 230 having an opened lower portion into the grooves 220a and 220b.

In the first step, the integration of the radio frequency circuit device 201 and the semiconductor die 202 is accomplished by various integration methods including wire bonding and solder bumping.

The semiconductor die 202 is partitioned into several segments by dicing after a semiconductor pattern is formed on a silicon wafer.

The second step is a process for forming the bumper pad 203. The bumper pad 203 comes into contact with the can 230, to secure the can 230 and to provide an electric ground. The bumper pad 203 may have a structure in which a ground pattern of a metal material is formed on the printed circuit board 210, such that a reflow process may be performed, and then a metal, such as lead, having a relatively low melting temperature is grown on the ground pattern.

The bumper pad 203 may be formed around a device which the electronic shield means, such as the can 230, is intended to enclose. In the present aspect of the invention, the electromagnetic wave shielding means is to enclose the radio frequency integrated circuit 201, which is illustrated as an example of the device. As such, FIG. 2-5 illustrate the bumper pad 203 being formed around the radio frequency integrated circuit 201. However, if necessary, the bumper pad 203 may be formed around the semiconductor die 202.

The third step is a process of forming a molding 220 that covers the upper portion 210 of the printed circuit board such that the radio frequency circuit device 201, the semiconductor die 202, and the bumper pad 203 are included within the molding 220. The molding 220 is accomplished by coating and curing a material capable of shielding electromagnetic wave.

The fourth step is a process of forming the grooves 220a and 220b on a portion of the molding 220 and inserting the can 230 into the grooves 220a and 220b. The grooves 220a and 220b are formed such that the bumper pad 203 is exposed. The can 230 may be secured to the bumper pad 203 using a reflowing method.

The can 230 is made of metal or any electrically conductive material, and the can 230 is electrically connected to the bumper pad 203.

In an electronic circuit package requiring electromagnetic shield, according to the present invention, it is possible to provide an electronic circuit package having a structure capable of individually shielding electromagnetic waves of the radio frequency circuit devices.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method for fabricating an electronic circuit package, the method comprising:
integrating at least one radio frequency circuit device and at least one semiconductor die on a printed circuit board;
forming a bumper pad made of metal material on the printed circuit board and around the radio frequency circuit device;
forming a molding on the printed circuit board to include the radio frequency circuit device and the semiconductor die within the molding; and
forming one or more grooves on a portion of the molding and inserting a can with an open lower portion into the groove.

2. The method as claimed in claim 1, wherein the grooves are formed such that the bumper pad is exposed.

3. The method as claimed in claim 1, wherein the can is electrically grounded to the bumper pad by a reflow process.

4. The method as claimed in claim 1, wherein the can is made of an electrically conductive material.

5. The method as claimed in claim 1, wherein the grooves are formed around a device requiring electromagnetic wave shield.

6. The method as claimed in claim 1, further comprising:
forming the bumper pad with a metal having a low melting temperature.

7. The method as claimed in claim 1, further comprising:
forming the bumper pad with lead.

8. The method as claimed in claim 1, further comprising:
forming the bumper pad by a reflow process.

9. The method as claimed in claim 1, further comprising:
forming the molding with a material capable of shielding electromagnetic waves.

10. An electronic circuit package comprising:
a printed circuit board;
at least one radio frequency circuit device and at least one semiconductor die that are integrated on the printed circuit board;
a molding formed on the printed circuit board so as to include the radio frequency circuit device and the semiconductor die within the molding;
a groove formed in the molding to enclose the circumference of the radio frequency circuit device; and
a can inserted into the groove.

11. The electronic circuit package as claimed in claim 10, further comprising a bumper pad made of metal material on the printed circuit board, the bumper pad providing an electrical ground connection for the can.

12. The electronic circuit package as claimed in claim 11, wherein the bumper pad is made of a metal having a low melting temperature.

13. The electronic circuit package as claimed in claim 11, where the bumper pad is made of lead.

14. The electronic circuit package as claimed in claim 10, wherein the molding is made of a material capable of shielding electromagnetic waves.
